(19) United States
(12) Patent Application Publication
(10) Pub. No.: US 2021/0203124 A1
(43) Pub. Date: Jul. 1, 2021

(54) HIGH POWER AND HIGH QUALITY LASER SYSTEM AND METHOD

(71) Applicant: Huawei Technologies Co., Ltd., Shenzhen (CN)

(72) Inventors: Ivan Nicolas CANO VALADEZ, Munich (DE); Romain BRENOT, Munich (DE); Derek NESSET, Munich (DE); Cao SHI, Dongguan (CN)

(21) Appl. No.: 17/203,337

(22) Filed: Mar. 16, 2021

Related U.S. Application Data
(63) Continuation of application No. PCT/EP2018/075079, filed on Sep. 17, 2018.

(51) Int. Cl. H01S 5/00; H01S 5/062; H01S 5/02251; H01S 5/50

(52) U.S. Cl. CPC H01S 5/0085; H01S 5/50; H01S 5/02251; H01S 5/06213

(57) ABSTRACT

A laser system is provided that includes a modulated laser, which is configured to generate an amplitude modulated laser signal, comprising a first amplitude modulation. The first amplitude modulation is based on a data signal. Moreover, the laser system includes an optical modulator, which is configured to receive the amplitude modulated laser signal as an input signal, and modulate the amplitude modulated laser signal with a second amplitude modulation, based on the data signal, resulting in an amplitude modulated output laser signal.

### CROSS-REFERENCE TO RELATED APPLICATIONS

This application is a continuation of International Application No. PCT/EP2018/075079, filed on Sep. 17, 2018, the disclosure of which is hereby incorporated by reference in its entirety.

### TECHNICAL FIELD

Embodiments of the disclosure relate to generating an amplitude modulated laser signal.

### BACKGROUND

For generating modulated laser signals, two basic principles have been used in the past. On the one hand, directly modulated lasers have been used. These devices provide a high optical output power, but have a limited extinction ratio while controlling eye quality and wavelength chirp. Also, these devices suffer from a high wavelength chirp, which causes a low tolerance to chromatic dispersion of a connected fiber, thus limiting the communication link length. Therefore, the main drawback of this solution is a trade-off between optical path penalty and extinction ratio.

On the other hand, electro-absorption modulated lasers (EMLs) have been used. These devices provide a high extinction ratio and, since the laser light is modulated externally, the signal has a low wavelength chirp and a high chromatic dispersion tolerance. This solution, therefore, results in a low optical path penalty and high extinction ratio. However, due to the modulator loss, the output power is significantly lower than that of a directly modulated laser. Furthermore, increasing the output power by increasing the laser current has limited benefits due to saturation effects in the electro-absorption modulator. Additionally, even if there is some increase in the optical output power, this method reduces the device efficiency as much of the increased laser power must be absorbed by the modulator during a ‘0’ bit. Also, the saturation effects in the modulator reduce the signal quality. These especially lead to eye mask violations and signal reception errors.

In order to achieve a high output power with a high signal quality, one solution is to add an optical amplifier to an electro-absorption modulated laser. This significantly increases the output power, while keeping the signal quality high. This solution though has the drawback of it requiring an additional optical element, which again increases the power consumption and the size of the device. This is especially problematic, since it increases the complexity and size of the device, as well as its power consumption.

### SUMMARY

Accordingly, the object of the present disclosure is to provide an apparatus and method, which allow for a high output power and high signal quality of an amplitude modulated laser signal.

The object is solved by the features of claim 1 for the system and claim 12 for the method. The dependent claims contain further developments.

According to a first aspect of the disclosure, a laser system is provided. This laser system comprises a modulated laser, which is configured to generate a modulated laser signal, comprising a first amplitude modulation. The first amplitude modulation is based on a data signal. Moreover, the laser system comprises an optical modulator, which is configured to receive the amplitude modulated laser signal as an input signal, and modulate the modulated laser signal with a second amplitude modulation, based on the data signal, resulting in an amplitude modulated output laser signal. This allows for a high optical output power, while maintaining a high signal quality.

In certain embodiments of the disclosure, the amplitude modulated output laser signal comprises an enhanced modulation depth and/or a higher extinction ratio than the modulated laser signal. An improvement of the output signal quality is thereby achieved. In addition, the amplitude modulation of the laser enables electro-absorption modulator (EAM) saturation effects to be reduced since the absorption needed from the EAM is lower and, as a result enables the EAM bias to be lower. Hence the output power is higher.

In further embodiments of the disclosure, the modulated laser is a single longitudinal mode laser, preferably a distributed feedback laser or a distributed Bragg reflector laser or a distributed reflector laser or a single wavelength vertical cavity laser or an external cavity laser, or a Fabry Perot laser, wherein the optical modulator is an electro-absorption modulator. This allows for a very flexible design of the laser system.

In certain embodiments of the disclosure, the laser system comprises a driver, which is configured for generating a first control signal for controlling the first amplitude modulation, based upon the data signal and generating a second control signal for controlling the second amplitude modulation, based upon the data signal. This allows for independently controlling the modulated laser and the optical modulator.

In certain embodiments of the disclosure, the driver is configured for generating the first control signal with identical logical polarity to the second control signal, preferably identical to the second control signal. This allows for a very simple driver.

Alternatively, the driver is configured for generating the first control signal different from the second control signal. This allows for an optimal control of the modulated laser and the optical modulator.

In further embodiments of the disclosure, the driver comprises a control signal determiner, configured to determine a first duty cycle of the first control signal and/or a first rise/fall time of the first control signal and/or a first crossing point of the first control signal and/or a first bias of the first control signal, wherein the first bias preferably is a bias current, and/or a second duty cycle of the second control signal and/or a second rise/fall time of the second control signal and/or a second crossing point of the second control signal and/or a second bias of the second control signal, wherein the second bias preferably is a bias voltage, and wherein the driver is configured for generating the first control signal with the first duty cycle and/or the first rise/fall time and/or the first crossing point and/or the first bias, and generating the second control signal with the second duty cycle and/or the second rise/fall time and/or the second crossing point and/or the second bias. This allows for an optimal control of the modulation.

Preferably, a duty cycle ratio is defined as the first duty cycle divided by the second duty cycle. The control signal determiner is configured to set the duty cycle ratio dependent upon a necessary output power of the amplitude modulated output laser signal and/or a necessary signal quality of the amplitude modulated output laser signal and/or a chromatic dispersion of a fiber link, the amplitude modulated output laser signal is supplied to and/or a length of a fiber in a fiber link, the amplitude modulated output laser signal is supplied to and/or a necessary reception power at a receiver connected to a fiber, the amplitude modulated output laser signal is supplied to and/or a temperature of the laser system. It is thereby possible to adapt the characteristics of the modulated signal to the circumstances.

In certain embodiments of the disclosure, the laser system moreover comprises an optical fiber, to which the amplitude modulated output laser signal is coupled. The driver then comprises a chromatic dispersion determiner, configured to determine a chromatic dispersion of the optical fiber. The control signal determiner is configured to generate the first control signal and the second control signal based upon the determined chromatic dispersion of the optical fiber. This allows for minimizing the effects of chromatic dispersion of the fiber.

In certain embodiments of the disclosure, the control signal determiner is configured to determine the first duty cycle of the first control signal and/or the first rise/fall time of the first control signal and/or the first crossing point of the first control signal and/or the first bias of the first control signal and/or the second duty cycle of the second control signal and/or the second rise/fall time of the second control signal and/or the second crossing point of the second control signal and/or the second bias of the second control signal based upon the determined chromatic dispersion of the optical fiber and/or based upon an allowed power penalty of the optical fiber. This allows for an especially accurate compensation for the effects of chromatic dispersion in the optical fiber.

In certain embodiments of the disclosure, the laser system additionally comprises an optical amplifier, which is configured to receive the amplitude modulated output laser signal from the optical modulator and amplify the amplitude modulated output laser signal. This allows for a further increase in output power.

According to a second aspect of the disclosure, a method for generating an amplitude modulated output laser signal is provided. The method comprises generating a modulated laser signal, comprising a first amplitude modulation, by a modulated laser, wherein the first amplitude modulation is based on a data signal, receiving the modulated laser signal as an input signal, by an optical modulator, and modulating the modulated laser signal with a second amplitude modulation also based upon the data signal, by the optical modulator, resulting in the amplitude modulated output laser signal. Since the optical modulator needs to absorb less power to achieve a certain extinction ratio, the modulator bias and the saturation effects are both reduced. This allows for generating the amplitude modulated output laser signal with a high signal quality and a high output power.

Generally, it has to be noted that all arrangements, devices, elements, units and means and so forth described in the present application could be implemented by software or hardware elements or any kind of combination thereof. Furthermore, the devices may be processors or may comprise processors, wherein the functions of the elements, units and means described in the present applications may be implemented in one or more processors. All steps which are performed by the various entities described in the present application as well as the functionality described to be performed by the various entities are intended to mean that the respective entity is adapted to or configured to perform the respective steps and functionalities. Even if in the following description or specific embodiments, a specific functionality or step to be performed by a general entity is not reflected in the description of a specific detailed element of that entity which performs that specific step or functionality, it should be clear for a skilled person that these methods and functionalities can be implemented in respect of software or hardware elements, or any kind of combination thereof.

### BRIEF DESCRIPTION OF DRAWINGS

FIG. 1 shows a first embodiment of the laser system of the first aspect of the disclosure;

FIG. 2a shows an exemplary eye diagram of a modulated laser signal generated by a modulated laser;

FIG. 2b shows an exemplary eye diagram of a laser signal modulated by an optical modulator;

FIG. 2c shows an eye diagram of an amplitude modulated output laser signal generated by an embodiment of the laser system according to the first aspect of the disclosure;

FIG. 2d shows an eye diagram of a laser signal modulated by an electro-absorption modulator where saturation effects are limiting the quality of the signal and causing eye mask violations.

FIG. 3 shows an exemplary eye diagram including parameters of the eye diagram;

FIG. 4 shows a second embodiment of the laser system of the first aspect of the disclosure;

FIG. 5 shows a third embodiment of the laser system according to the first aspect of the disclosure, and

FIG. 6 shows an embodiment of the method of the second aspect of the disclosure as a flow diagram.

### DESCRIPTION OF EMBODIMENTS

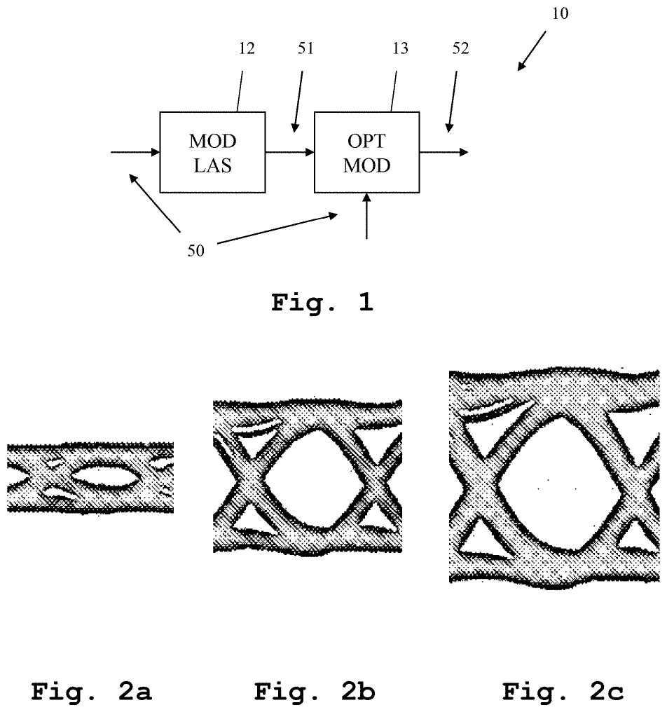

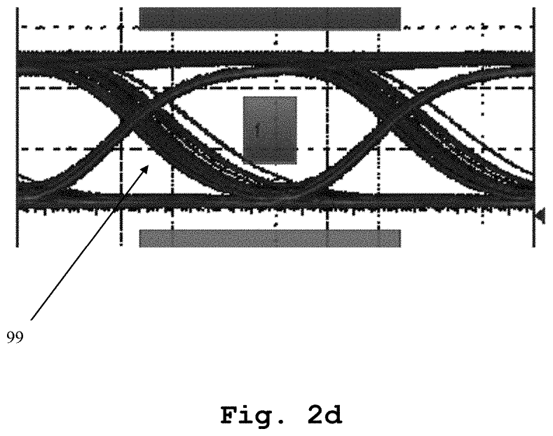

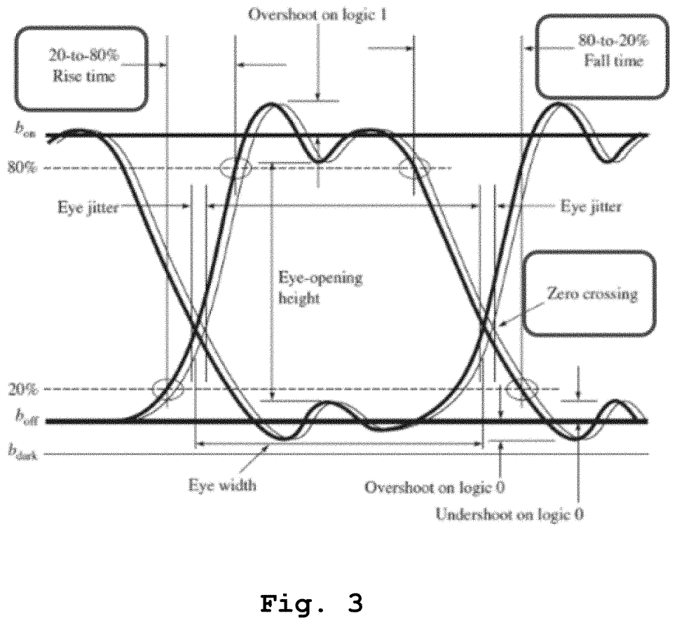

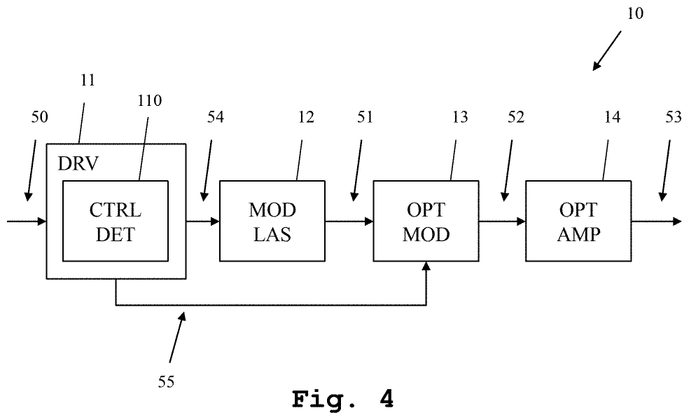

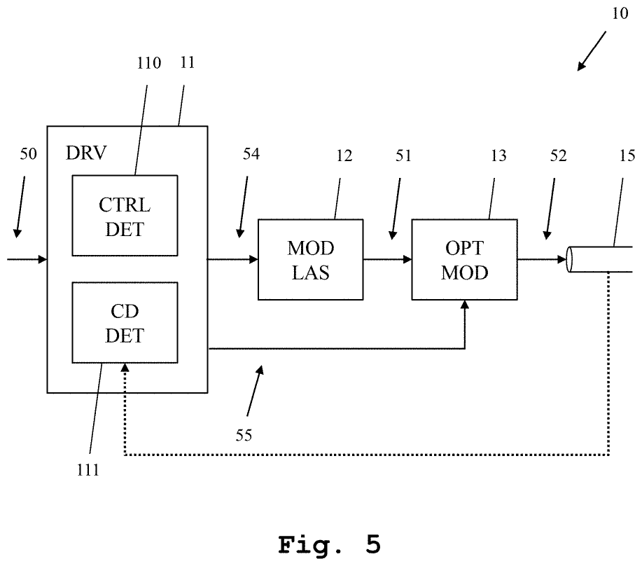

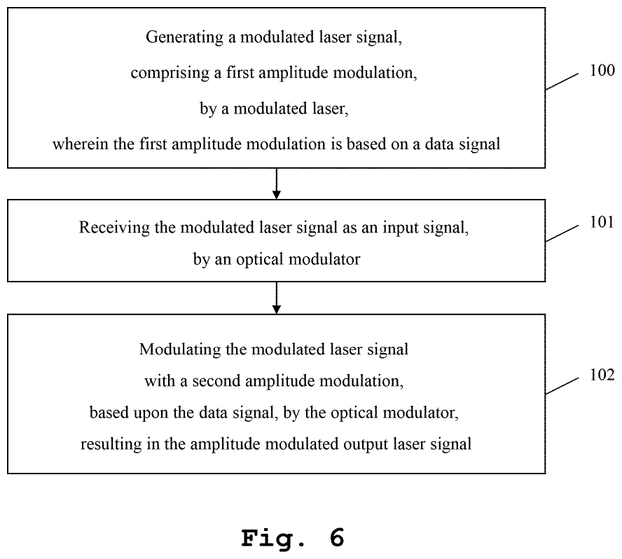

First, we demonstrate the general construction of an embodiment of the laser system with regard to FIG. 1. With regard to FIGS. 2a, 2b, 2c, 2d and 3, we then show benefits of the disclosure. Along FIG. 4 and FIG. 5, further embodiments of the laser system according to the first aspect are shown and described in detail. Finally, with regard to FIG. 6, the function of an embodiment of the method according to the second aspect of the disclosure is shown in detail. Similar entities and reference numbers in different figures have been partially omitted.

In FIG. 1, a first embodiment of the device according to the first aspect of the disclosure is shown. A laser system 10 comprises a modulated laser 12, preferably a single longitudinal mode laser, especially a distributed feedback laser or a distributed Bragg reflector laser, or a distributed reflector laser or a single wavelength vertical cavity laser or an external cavity laser, or a Fabry Perot laser. The modulated laser 12 is connected to an optical modulator 13, which advantageously is an electro-absorption modulator.

A data signal 50 is provided to the modulated laser 12 and to the optical modulator 13. Alternatively, respective control signals, which may differ from each other, may be provided to the modulated laser 12 and the optical modulator 13. This is shown in detail in FIG. 4 and FIG. 5.

Based upon the data signal 50, the modulated laser 12 is configured to generate a modulated laser signal 51, comprising a first amplitude modulation. The optical modulator 13 receives this amplitude modulated laser signal 51 as an input signal and modulates the modulated laser signal 51 with a second amplitude modulation, also based upon the data signal 50. This results in an amplitude modulated output laser signal 52.

It should be noted that the modulated laser 12 as well as the optical modulator 13 each have input electrical lines which are able to handle high-frequency signals, e.g. higher than 1 GHz. Into these input lines, either in the data signal 50 can be input directly, or a driver can be used for generating independent control signals, as shown in FIG. 4 and FIG. 5.

The disclosure therefore solves the above stated problem specially, the disclosure solves the problem of getting high output power and signal quality.

Increasing the laser power results in saturation effects in the EAM, as can be seen in FIG. 2d highlighted as reference number 99. This can be offset by increasing the EAM bias. But the latter reduces the optical power. Therefore, the disclosure modulates the laser 12 producing an amplitude modulated laser signal 51 which in general will have relatively low extinction ratio 52. The laser modulated signal 51 reduces the power in the “0” levels entering into the EAM. The optical modulator 13 then needs to absorb less power from the amplitude modulated laser signal 51 and so the saturation effects on the optical modulator 13 are reduced. By reducing the saturation effects then the optical modulator 13 can work at a lower bias point and introduce less losses. In other words, the solution consists of modulating both the primary laser—the modulated laser 12, and the optical modulator 13 simultaneously with the same data.

Accordingly, the modulated laser 12 will be modulated with a relatively low extinction ratio, so as to limit its wavelength chirp and the optical modulator 13 does further carve the signal to increase its extinction ratio and decrease the transient wavelength chirp through temporal carving. Since the optical modulator 13 will not need to have a high extinction ratio it can be biased at a less negative voltage and thus, absorb less optical power. Additionally, the low signal level from the modulated laser in the ‘zeros’ reduces the optical modulator saturation effects that cause eye mask violations, as can be seen in FIG. 2d as reference number 99. As a result, a transmitter using the laser system 10 will produce a high optical power with sufficient extinction ratio and eye quality. Furthermore, the optical modulator length can be shortened compared to a typical/conventional EML to further reduce the absorption and increase the optical power even more.

The following advantages can be achieved with this solution:
Lower mean modulated laser current resulting in a reduced power consumption by the modulated laser 12
Reduced cooling power for cooling an optical chip, into which the laser system may be integrated
Increased output power by up to 2 dB through reduced optical modulator 13 saturation effects
Increased output power by enabling operation at a lower absorption optical modulator 13 bias point
Additional power gain is possible with a shorter optical modulator 13
Modulated laser 12 transient wavelength chirp “carving” by optical modulator 13 reduces optical path penalty vs. only using a modulated laser
Unlike conventional optical modulator devices, output power can be traded-off with optical path penalty and adapted to a chromatic dispersion the signal will face during fiber transmission, e.g. O-band vs L-band or 10 km vs 20 km
Can be used with integrated amplifier, as shown in FIG. 4 to further increase the power, interesting for bitrates >25 Gb/s where even higher optical power will be needed
Increased output power by reducing the total optical absorption of the optical modulator 13 through reduced bias and/or shorter length
Through amplitude modulating the modulated laser 12, the low signal level from the modulated laser 12 in the “zeros” reduces the optical modulator 13 saturation effects which cause eye mask violations allowing to use a lower bias and thus higher output power
Saturation effects are enhanced at lower bias voltages so this effect is also compensated by the laser modulation
The optical path penalty caused by the wavelength chirp of the laser is limited by using a low extinction ratio direct modulated laser 51 signal whose “zero” level is further lowered by an optical modulation in the optical modulator 13 for achieving a high extinction ratio optical signal 52

In FIG. 2a a resulting eye diagram of an output signal of a modulated laser is shown. It can be seen that the opening of the eye is relatively small.

In FIG. 2b, an eye diagram of an output signal of an optical modulator is shown. Here, the opening of the eye is already larger than shown in FIG. 2a.

In FIG. 2c, an eye diagram of the output signal 52 of the inventive laser system shown in FIG. 1 is shown. Here, it can clearly be seen that a high output power as well as a high signal quality is achieved. Especially, this can be seen from the large opening height of the eye in the eye diagram.

In FIG. 2d, an eye diagram of a laser signal modulated by an electro-absorption modulator is shown. Here especially the saturation effects 99 limiting the quality of the signal are highlighted.

In FIG. 3, a general representation of an eye diagram is shown. Especially, different parameters relevant in an eye diagram are highlighted. Especially obvious is the rise time, the fall time, the zero crossings, the eye opening height, the eye width.

In FIG. 4, a further embodiment of the laser system 10 of the first aspect of the disclosure is shown. In comparison to FIG. 1, here the modulated laser 12 and the optical modulator 13 are no longer directly provided with the data signal 50, but a driver 11 is connected in between.

The driver 11 receives the data signal 50 and generates a first control signal 54 for controlling the operation of the modulated laser 12 and a second control signal 55 for operating the optical modulator 13 therefrom, and provides the control signals 54, 55 to their respective destinations. Especially, the first control signal 54 is provided to the modulated laser 12, while the control signal 55 is provided to the optical modulator 13.

Additionally, the driver 11 comprises a control signal determiner 110. The control signal determiner 110 determines a duty cycle of the first control signal 54 and the second control signal 55.

A duty cycle is the ratio between the duration of the “1” bit and the “0” bit in the constant or stationary phase of the pulse. The duty-cycle ratio is the duty-cycle of the laser divided by the duty cycle of the modulator. The crossing point and rise/fall time of the pulse can contribute to modifying the duty cycle.

Especially, the control signal determiner determines a first duty cycle of the first control signal and/or a first rise/fall time of the first control signal and/or a first crossing point of the first control signal and/or a first bias of the first control signal, wherein the first bias preferably is a bias current, and/or a second duty cycle of the second control signal and/or a second rise/fall time of the second control signal and/or a second crossing point of the second control signal and/or a second bias of the second control signal, wherein the second bias preferably is a bias voltage.

The driver 11 then generates the first control signal 54 and the second control signal 55 based upon the determined control signal parameters of the control signal determiner 110.

A duty cycle ratio may be defined as the first duty cycle divided by the second duty cycle. The control signal determiner is then adapted to set the duty cycle ratio dependent upon a necessary output power of the amplitude modulated output laser signal 52 and/or a necessary signal quality of the amplitude modulated output laser signal 52 and/or a link chromatic dispersion of a fiber link, the amplitude modulated output laser signal 52 is supplied to and/or a length of a fiber of a fiber link, the amplitude modulated output laser signal 52 is supplied to and/or a necessary reception power at a receiver connected to a fiber, the amplitude modulated output laser signal 52 is supplied to and/or a temperature.

It should be noted that although not displayed here, in case of using a temperature as an input parameter, the laser system 10 then comprises either an interface for receiving a temperature signal or a temperature sensor for determining the temperature.

In the embodiment shown here in FIG. 4, the laser system 10 additionally comprises an optical amplifier 14, which is provided with the amplitude modulated output laser signal 52 by the optical modulator 13. The optical amplifier 14 performs an amplification resulting in an amplified amplitude modulated output laser signal 53. The optical amplifier 14 though is only an optional component. It can be used for further increasing the output power, comes at the cost of an additional component and additional power requirement, though.

At the beginning of the communication, the duty-cycle ratio is set and it nominally remains constant during operation. This ratio is determined by parameters such as the output power needed, the transmitted and received signal quality targets, the total link chromatic dispersion, the length of the fiber, the power needed at the receiver, and the temperature.

Also, in a transitory phase of the pulse, the crossing point of the signals can be controlled to modify the duration of the “1” and “0” bits. A higher crossing points means that the duration of the “1” is longer than the “0” duration. This longer “1” will produce a higher duty-cycle.

Another feature of the pulse that can be controlled is the rise/fall time. By changing this parameter, the duration of the “1” and “0” can be modified resulting in a change on the duty-cycle.

A longer rise-time means that the transition from “0” to “1” takes more time, reducing the stationary time in the “1” state and increasing it in the “0” level. As a result, the duty cycle is modified.

In general, the rise and fall times can be independently controlled in order to optimize the transmitter parameters and adapt to the application scenario requirements.

In addition, the optical modulator 13 length can be reduced to allow a smaller intrinsic absorption since its extinction ratio is lower than in a conventional optical modulator based laser system. Typically, the length is 150-200 μm for 10G, 100-150 μm for 25G, and 50-75 μm for 50G. For the proposed shortening of the optical modulator 13, the values would be different and need to be specifically designed, e.g., for 10G, the length could be around 125 um.

Finally, the device can be configured to adapt the signal according to the chromatic dispersion in a fiber by choosing the extinction ratio for the pulses of the control signal of each module, comprising the modulated laser 12 and the optical modulations 13.

This is shown in FIG. 5. Here, the laser system 10 additionally comprises an optical fiber 15, which is connected to the optical modulator 13. The optical fiber 15 is supplied with the amplitude modulated output laser signal 52. Moreover, the driver 11 here comprises a chromatic dispersion determiner 111. The chromatic dispersion determiner determines a chromatic dispersion of the optical fiber 15. This can be done for example by receiving signals through the optical fiber 15, or by directly receiving the chromatic dispersion parameters from an external device, for example a receiver connected to the other end of the optical fiber 15. The chromatic dispersion determiner 111 hands on the determined chromatic dispersion to the control signal determiner, which generates the first control signal 54 and the second control signal 55 based upon the determined chromatic dispersion of the optical fiber 15.

Especially, the control signal determiner 110 determines the first duty cycle of the first control signal and/or the first rise/fall time of the first control signal and/or the first crossing point of the first control signal and/or the first bias of the first control signal and/or the second duty cycle of the second control signal and/or the second rise/fall time of the second control signal and/or the second crossing point of the second control signal and/or the second bias of the second control signal based upon the determined chromatic dispersion of the optical fiber 15 and/or based upon an allowed power penalty of the optical fiber 15.

Finally, in FIG. 6, an embodiment of the method according to the second aspect of the disclosure is shown. The method and the system of the present disclosure very closely correspond. Therefore, elaborations regarding the system are also applicable to the method.

In a first step 100, a modulated laser signal is generated by a modulated laser. The modulated laser signal comprises a first amplitude modulation. This first amplitude modulation is based on a data signal.

In a second step 101, the modulated laser signal is received as an input signal, by an optical modulator.

In a final third step 102, the modulated laser signal is modulated with a second amplitude modulation by the optical modulator. This second amplitude modulation is also based upon the data signal. The second amplitude modulation results in an amplitude modulated output laser signal.

The disclosure is not limited to the examples and especially not to any mentioned communication standards or frequencies. Also, the types of applicable modulated lasers and optical modulators should not be understood as limited to the provided examples. The disclosure discussed above can be applied to many different communications tasks. The characteristics of the exemplary embodiments can be used in any advantageous combination.

The disclosure has been described in conjunction with various embodiments herein. However, other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in usually different dependent claims does not indicate that a combination of these measures cannot be used to advantage. A computer program may be stored/distributed on a suitable medium, such as an optical storage medium or a solid-state medium supplied together with or as part of other hardware, but may also be distributed in other forms, such as via the internet or other wired or wireless communication systems.

What is claimed is:

1. A laser system comprising:
a modulated laser, configured to generate an amplitude modulated laser signal, comprising a first amplitude modulation, wherein the first amplitude modulation is based on a data signal; and
an optical modulator, configured to:
receive the amplitude modulated laser signal as an input signal; and
modulate the amplitude modulated laser signal with a second amplitude modulation, based on the data signal, resulting in an amplitude modulated output laser signal.

2. The laser system of claim 1,
wherein the amplitude modulated output laser signal comprises one or more of an enhanced modulation depth or a higher extinction ratio than the amplitude modulated laser signal.

3. The laser system of claim 1,
wherein the modulated laser is one of: a single longitudinal mode laser, wherein the single longitudinal mode laser is one of: a distributed feedback laser, a distributed bragg reflector laser, a distributed reflector laser, a single wavelength vertical cavity laser, or an external cavity laser; or
a Fabry-Perot Laser, and
wherein the optical modulator is an electro-absorption modulator.

4. The laser system of claim 1,
further comprising a driver, the driver configured for:
generating a first control signal for controlling the first amplitude modulation, based upon the data signal; and
generating a second control signal for controlling the second amplitude modulation, based upon the data signal.

5. The laser system of claim 4,
wherein the driver is configured for generating the first control signal with identical logical polarity to the second control signal.

6. The laser system of claim 4,
wherein the first control signal is different from the second control signal.

7. The laser system of claim 4,
wherein the driver comprises a control signal determiner, configured to determine one or more of:
a first duty cycle of the first control signal;
a first rise/fall-time of the first control signal;
a first crossing point of the first control signal;
a first bias of the first control signal, wherein the first bias is a bias current;
a second duty cycle of the second control signal;
a second rise/fall-time of the second control signal;
a second crossing point of the second control signal; or
a second bias of the second control signal, wherein the second bias preferably is a bias voltage, and
wherein the driver is configured for:
generating the first control signal with one or more of: the first duty cycle, the first rise/fall-time, the first crossing point, or the first bias; and
generating the second control signal with one or more of: the second duty cycle, the second rise/fall-time, the second crossing point, or the second bias.

8. The laser system of claim 7,
wherein a duty cycle ratio is defined as the first duty cycle divided by the second duty cycle, and
wherein the control signal determiner is configured to set the duty cycle ratio dependent upon one or more of:
a necessary output power of the amplitude modulated output laser signal;
a necessary signal quality of the amplitude modulated output laser signal;
a link dispersion of a fiber link the amplitude modulated output laser signal is supplied to;
a length of a fiber of a fiber link the amplitude modulated output laser signal is supplied to;
a necessary reception power at a receiver connected to a fiber the amplitude modulated output laser signal is supplied to; or
a temperature.

9. The laser system of claim 7,
wherein the laser system comprises an optical fiber to which the amplitude modulated output laser signal is coupled,
wherein the driver comprises a chromatic dispersion determiner configured to determine a chromatic dispersion of the optical fiber, and
wherein the control signal determiner is configured to generate the first control signal and the second control signal based upon the determined chromatic dispersion of the optical fiber.

10. The laser system of claim 9,
wherein, based upon one or more of the determined chromatic dispersion of the optical fiber or an allowed power penalty on the optical fiber, the control signal determiner is configured to determine one or more of:
the first duty cycle of the first control signal;
the first rise/fall-time of the first control signal;
the first crossing point of the first control signal;
the first bias of the first control signal;
the second duty cycle of the second control signal;
the second rise/fall-time of the second control signal;
the second crossing point of the second control signal; or
the second bias of the second control signal.

11. The laser system of claim 1,
further comprising an optical amplifier configured to:
receive the amplitude modulated output laser signal from the optical modulator; and
amplify the amplitude modulated output laser signal.

12. A method for generating an amplitude modulated output laser signal, the method comprising:
generating, by a modulated laser, an amplitude modulated laser signal, comprising a first amplitude modulation, wherein the first amplitude modulation is based on a data signal;
receiving, by an optical modulator, the amplitude modulated laser signal as an input signal; and
modulating, by the optical modulator, the amplitude modulated laser signal with a second amplitude modulation, based upon the data signal to obtain an amplitude modulated output laser signal.
